(19) United States
(12) Patent Application Publication
(10) Pub. No.: US 2024/0072792 A1
(43) Pub. Date: Feb. 29, 2024

(54) SEMICONDUCTOR DEVICE

(71) Applicant: LAPIS Technology Co., Ltd., Yokohama (JP)

(72) Inventor: Koya SHIMAZAKI, Yokohama (JP)

(73) Assignee: LAPIS Technology Co., Ltd., Yokohama (JP)

(21) Appl. No.: 18/455,466

(22) Filed: Aug. 24, 2023

(30) Foreign Application Priority Data
Aug. 31, 2022 (JP) 2022-138582

(51) Int. Cl. H03K 17/22; H03K 3/037

(52) U.S. Cl. CPC H03K 17/223; H03K 3/037

(57) ABSTRACT

A semiconductor device includes two power-on reset (POR) circuits having different response characteristics to a change in power voltage in generating and outputting a reset signal by detecting a change in voltage value of the power voltage, and a selector. The selector selects a reset signal outputted from one of the two POR circuits based on an inputted selection control signal, and outputs the selected signal as a reset signal.

### CROSS REFERENCE TO RELATED APPLICATION

This application is based upon and claims the benefit of priority of the prior Japanese Patent Application No. 2022-138582, filed on Aug. 31, 2022, the entire contents of which are incorporated herein by reference.

### TECHNICAL FIELD

The disclosure relates to a semiconductor device including a power-on reset circuit.

### BACKGROUND ART

Semiconductor devices such as LSIs (large-scale integrated circuits) use a power-on reset circuit (referred to as a POR circuit below) in order to prevent an erroneous operation upon turning on and turning off. This POR circuit generates and outputs a reset signal by detecting a change in voltage value of the power voltage. Specifically, the POR circuit generates and outputs a reset signal that becomes inactive (reset is being disabled) if the power voltage reaches the operating voltage when the semiconductor device is turned on, and that becomes active (preventing the semiconductor device from operating) before the power voltage goes below the operating voltage.

For example, Japanese Patent Application Laid-open Publication No. 2014-68226 discloses a power-on reset circuit that can reliably detect a decrease of the power voltage.

Generally, when the power voltage of a semiconductor device such as an LSI lowers, the LSI is brought into a reset state by the POR circuit. However, the response characteristics (a threshold voltage at which a reset signal is issued, a time required for the reset signal to be issued after the power voltage reaches the threshold value, or the like) of the POR circuit to a change in power voltage were not adjustable.

However, depending on the products for which the LSI is used or the usage environment thereof, the optimal response characteristics of the POR circuit may vary, and as for the response to an unexpected change in power voltage in particular, a quick response where a reset signal is issued immediately after the power voltage lowers for a short period of time is needed in some cases, whereas an overly quick response should be avoided in other cases.

### SUMMARY OF THE INVENTION

### Problems to be Solved by the Invention

The disclosure is aiming at providing a semiconductor device that can adjust the response characteristics of a power-on reset circuit to a change in power voltage in accordance with the usage environment of a product for which the semiconductor device is used.

In order to solve the above-mentioned problem, a semiconductor device of the disclosure includes: a plurality of power-on reset circuits having different response characteristics to a change in power voltage in generating and outputting a reset signal after detecting a change in voltage value of the power voltage; and a selector that selects a reset signal outputted from one of the plurality of power-on reset circuits based on an inputted selection control signal.

In order to solve the above-mentioned problem, another semiconductor device of the disclosure includes: a power-on reset circuit that can switch between different response characteristics to a change in power voltage according to a predetermined setting value in generating and outputting a reset signal after detecting a change in voltage value of the power voltage; and a selector that selects one of a plurality of setting values for setting the response characteristics based on an inputted selection control signal, and applies the setting value to the power-on reset circuit.

In order to solve the above-mentioned problem, yet another semiconductor device of the disclosure includes: a power-on reset circuit that can switch between different response characteristics to a change in power voltage based on a combination of logic values or states of a plurality of selection control signals that are externally inputted; and a plurality of holding circuits that respectively hold the logic values or states of the plurality of selection control signals.

### BRIEF DESCRIPTION OF THE DRAWINGS

FIG. 1 is a diagram illustrating an operation of outputting a reset signal by a typical POR circuit provided in a semiconductor device.

FIG. 2 is a diagram illustrating an example of a circuit configuration of a circuit for generating a reset signal provided in a semiconductor device of an embodiment of the disclosure.

FIG. 3 is a diagram illustrating an example of a circuit configuration of a circuit for generating a reset signal provided in a semiconductor device of an embodiment of the disclosure.

FIG. 4 is a diagram illustrating an example of a circuit configuration for holding the logical setting of a selection control signal 102.

FIG. 5 is a diagram illustrating another example of a circuit configuration for holding the logical setting of the selection control signal 102.

FIG. 6 is a diagram illustrating an example of a circuit configuration of a latch circuit 70 in the circuit configuration illustrated in FIG. 5.

FIG. 7 is a diagram illustrating a circuit configuration for controlling a POR circuit that can set response characteristics through a plurality of bits.

### DETAILED DESCRIPTION OF EMBODIMENTS

According to the disclosure, the response characteristics of a power-on reset circuit to a change in power voltage can be adjusted based on the usage environment of a product for which the power-on reset circuit is used.

Next, embodiments of the disclosure will be explained in detail with reference to figures.

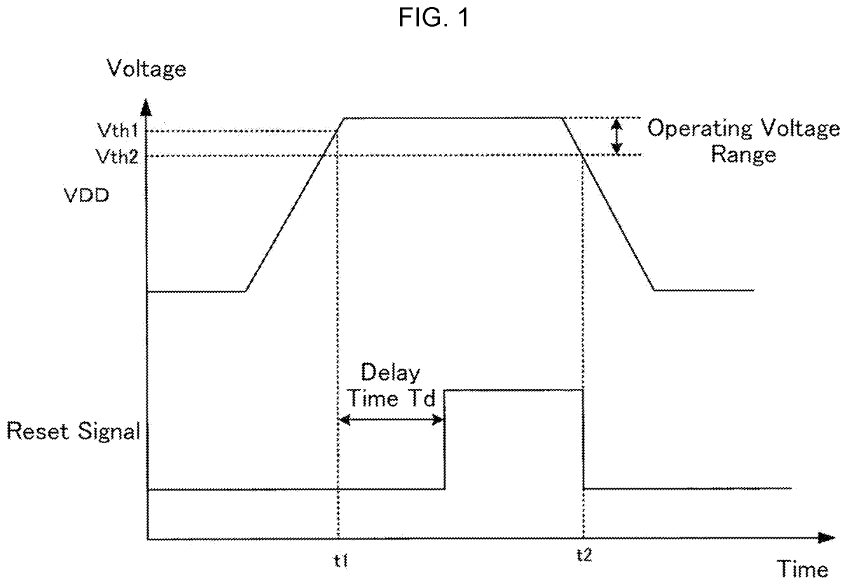

First, before explaining the semiconductor device of one embodiment of the disclosure, how a reset signal is outputted by a typical POR circuit provided in a semiconductor device will be explained with reference to FIG. 1.

The reset signal is an L-active signal that enters a reset-enabling state at a low level (hereinafter, L), and that enters a reset-disabling state at a high level (hereinafter H).

When a CPU is operated by a VDD power voltage, for example, the POR circuit monitors a change in voltage value of the VDD power voltage, and generates and outputs a reset signal. When the voltage value of the VDD power voltage drops, the POR circuit sets the reset signal to L before the voltage value goes below the operating voltage range. Also, when the VDD power voltage rises, the POR circuit detects the voltage value entering the operating voltage range, and sets the reset signal to H to bring it to the reset disabling state. Specifically, when the power is turned on, as illustrated in FIG. 1, the reset signal is set to H when the delay time td has passed after VDD reached the threshold voltage Vth1 at Time t1. When the voltage value of the VDD power voltage drops and reaches the threshold voltage Vth2 at a time t2, the reset signal is set to L.

The response characteristics of the POR circuit mean the threshold value for detecting a change in power voltage, as well as the delay time that indicates a time period between the time when the voltage value of the power voltage reaches the threshold value and the time when the reset signal is outputted as described above.

The response characteristics of the POR circuit change depending on how this threshold value is set, and how this delay time is set.

Next, a semiconductor device of an embodiment of the disclosure will be explained.

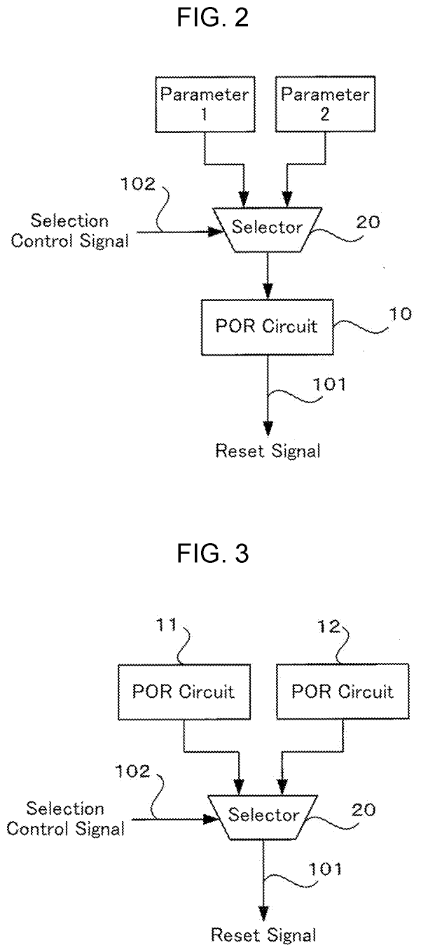

FIGS. 2 and 3 are diagrams each illustrating an example of the circuit configuration of the circuit for generating a reset signal provided in a semiconductor device of this embodiment.

The circuit configuration illustrated in FIG. 2 includes a POR circuit 10 that can change the response characteristics to a change in power voltage in generating and outputting a reset signal after detecting the change in voltage value of the power voltage, and a selector 20.

The selector 20 selects one of a plurality of parameters for setting the response characteristics based on the inputted selection control signal 102, and provides the POR circuit 10 with the selected parameter. Specifically, the selector 20 provides the POR circuit 10 with either Parameter 1 or Parameter 2 depending on the logic value or state of the selection control signal 102. For example, when the selection control signal 102 is H, the selector 20 selects Parameter 1 for the POR circuit 10, and when the selection control signal 102 is L, the selector 20 selects Parameter 2 for the POR circuit 10.

The POR circuit 10 generates a reset signal 101 having the response characteristics based on the parameter provided by the selector 20, and outputs the reset signal.

The circuit configuration illustrated in FIG. 3 includes two POR circuits 11 and 12 having differing response characteristics to a change in power voltage in generating and outputting a reset signal after detecting a change in voltage value of the power voltage, and a selector 20. The selector 20 selects a reset signal outputted from either one of the two POR circuits 11 and 12 based on the inputted selection control signal 102, and outputs the selected reset signal as a reset signal 101.

According to the circuit configurations illustrated in FIGS. 2 and 3, by changing the logic value or state of the selection control signal 102, the response characteristics of the POR circuit to a change in power source voltage can be adjusted to response characteristics that are suitable for the usage environment of a product for which the POR circuit is used.

The response characteristics are the threshold voltage for detecting a change in power voltage and/or the delay time, which is a period of time between when the voltage value of the power voltage reaches the threshold voltage and when the time when a reset signal is outputted.

When the response characteristics of the circuit generating the reset signal 101 to a change in power voltage are to be changed as described above, the logical setting of the selection control signal 102 for changing the response characteristics needs to be maintained even after the power voltage goes lower than the operating voltage of the internal circuits of an LSI.

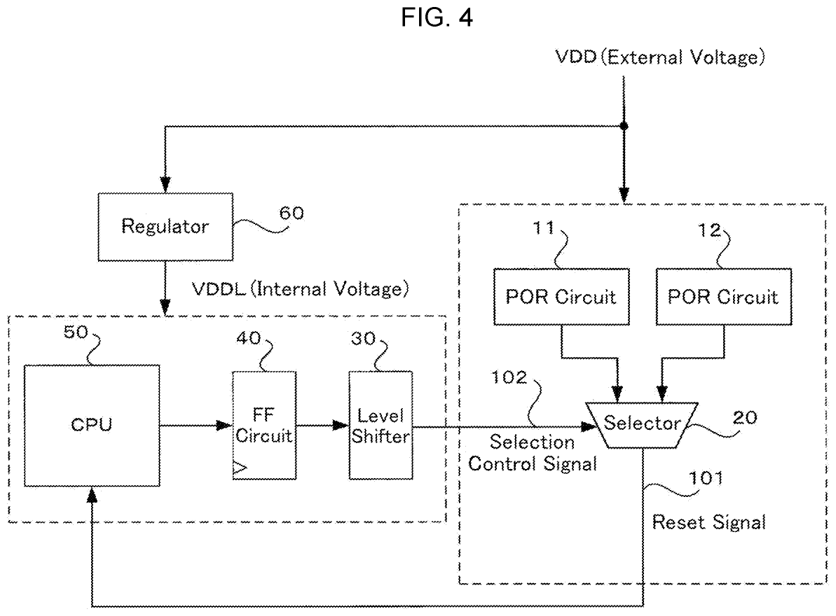

Thus, the circuit configuration illustrated in FIG. 4 is employed as a circuit configuration to maintain the logic setting of the selection control signal 102, for example.

In the circuit configuration illustrated in FIG. 4, a VDD power voltage, which is an external power voltage supplied from the outside of the LSI, is supplied to the POR circuits 11 and 12 and the selector 20. In addition, as a holding circuit for holding the logic value or state of the selection control signal 102, a level shifter 30 and a flip-flop circuit (referred to as FF circuit below) 40 are provided.

A CPU 50 writes a logic value or state representing the desired response characteristics to the FF circuit 40 in an initial sequence or the like upon turning on the LSI. The logic value or state written to the FF circuit 40 is outputted to the selector 20 as the selection control signal 102 via the level shifter 30.

The level shifter 30, FF circuit 40, and CPU 50 are supplied with VDDL, which is an internal power voltage having a voltage value lower than that of VDD (external power voltage). This VDDL (internal power voltage) is generated by a regulator 60, which is a rated voltage circuit using the external VDD power voltage as an input. For example, VDD is an external power voltage of 5V, and VDDL is an internal power voltage of 1.5V.

The level shifter 30 is a circuit for shifting the voltage value of the output signal of the FF circuit 40 from 1.5V to 5V, and outputting the signal to the selector 20 as the selection control signal 102.

As described above, in the circuit configuration illustrated in FIG. 4, the external power voltage VDD is used for the power voltage to drive the selector 20, and the internal power voltage VDDL generated internally within the device is used for the power voltage to drive the FF circuit 40.

The VDDL generated by the regulator 60 is less susceptible to the noise and is a more stable power voltage as compared with the external voltage VDD. The regulator 60 generates VDDL (1.5V) from VDD (5V), and thus, even if the voltage value of VDD lowers (e.g., becomes lower), VDDL, which is outputted as 1.5V, is less likely to be affected. Also, the circuit is often configured such that a capacitor is provided at the output or the like of the regulator 60 to keep the voltage value of VDDL from being affected by a change in voltage value of VDD.

Therefore, even if the voltage value of VDD, which is an external power voltage, temporarily lowers due to noise and the like, as long as the voltage value of VDDL that is the power voltage for the FF circuit 40 that holds the logic value or state determining the response characteristics is stable, the response characteristics in generating the reset signal are maintained.

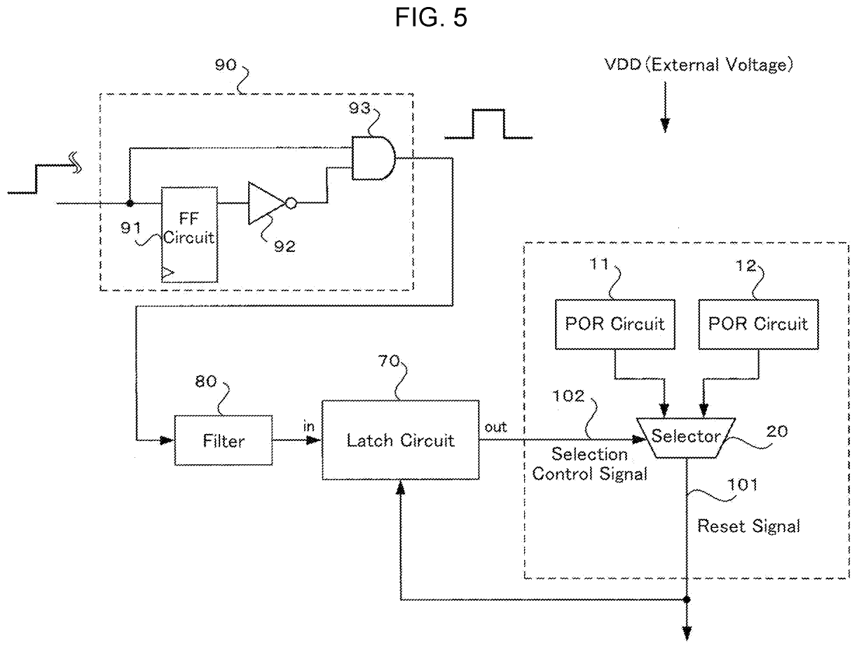

FIG. 5 illustrates another example of the circuit configuration for holding the logic setting of the selection control signal 102.

In the circuit configuration of FIG. 5, a latch circuit 70, a filter 80, and a one-shot pulse signal generating circuit 90 are provided as a holding circuit for the logic setting of the selection control signal 102.

The one-shot pulse signal generating circuit 90 is a circuit that generates and outputs a pulse signal that stays at H only for a period of time equivalent to one clock. That is, the one-shot pulse signal generating circuit 90 generates a pulse signal having a predetermined pulse width.

The one-shot pulse signal generating circuit 90 is constituted of an FF circuit 91, an inverter 92, and an AND gate (AND circuit) 93.

The filter 80 removes noise components from a signal outputted from the one-short pulse signal generating circuit 90.

When the logic value or state of the selection control signal 102 is to be changed, the latch circuit 70 receives either an input of the pulse signal generated by the one-shot pulse signal generating circuit 90 via the filter 80, or the reset signal 101 to be reset, which changes the logic value or state of the selection control signal 101 to be outputted.

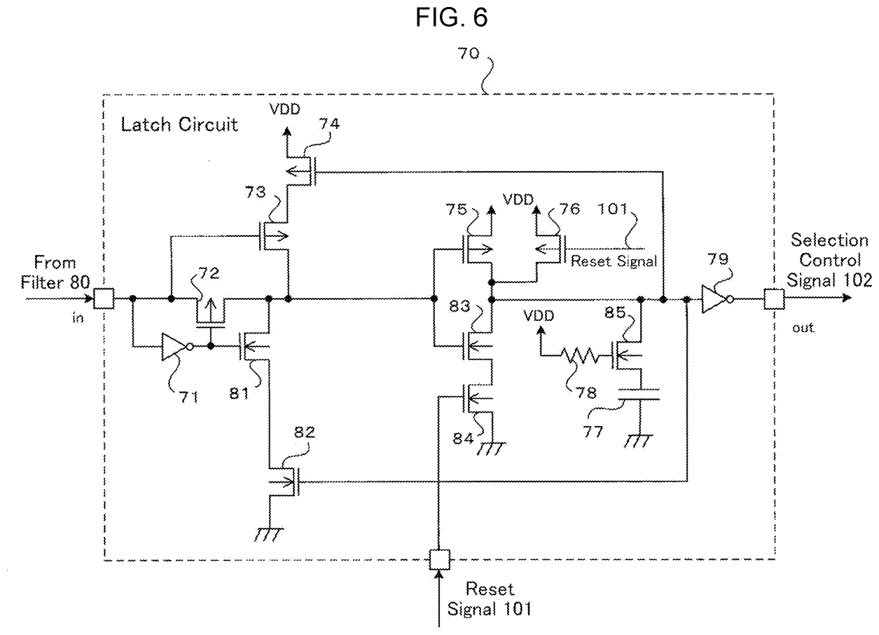

Next, one example of the specific circuit configuration of the latch circuit 70 in the circuit configuration of FIG. 5 is illustrated in FIG. 6.

As seen in FIG. 6, the latch circuit 70 is constituted of an inverter 71, P-channel type FETs 72 to 76, a capacitor 77, a resistor element 78, an inverter 79, and N-channel type FETs 81 to 85.

With this circuit configuration illustrated in FIG. 6, in the latch circuit 70, the data input doubles as a gate signal, and the gate opens for a one clock cycle only when H is written to. Thus, H is written to the latch circuit 70 when the pulse signal of one clock, which is generated by the one-shot pulse signal generating circuit 90, is inputted, and as a result, the latch circuit 70 outputs the selection control signal 102 with the logic value or state being H. Thereafter, when VDD lowers and the reset signal 101 is outputted, or in other words, when the reset signal 101 becomes L, the latch circuit 70 is reset and L is written thereto.

That is, in the initial state of the LSI upon start-up, the latch circuit 70 holds L, and when the CPU 50 writes H to the FF circuit 91 in the initial sequence or the like, the pulse signal of one clock is generated by the one-shot pulse signal generating circuit 90, which causes the latch circuit 70 to output L. If H is not written to the FF circuit 91 in the initial sequence or the like, the output of the latch circuit 70 maintains the initial state, which is L.

The filter 80 is provided to keep H from being written to the latch circuit 70 when a narrow pulse occurs at the input of the latch circuit 70 due to noise or the like.

As illustrated in FIG. 6, the latch circuit 70 also includes the capacitor 77 for holding the logic state of the selection control signal 102 when the power voltage drops. Therefore, even if the power voltage drops temporarily due to noise or the like, the electrical charges are maintained by the capacitor 77 inside the latch circuit 70, which makes it possible to hold the logic setting of the selection control signal 102 outputted from the latch circuit 70.

With the circuit configuration illustrated in FIG. 5, it is possible to maintain the logic setting of the selection control signal 102 even if the entire circuit is driven by the external power voltage VDD, for example. That is, according to the circuit configuration of FIG. 5, it is possible to maintain the logic setting of the selection control signal 102 without providing, in addition to the external power voltage, an internal power voltage that is less susceptible to noise as illustrated in FIG. 4. This means the circuit configuration of FIG. 5 is also applicable to an LSI having a single power source.

Furthermore, in the circuit configurations of FIGS. 4 and 5 described above, the logic value or state of the selection control signal 102 was maintained even after the output is switched between the two POR circuits 11 and 12 illustrated in FIG. 3, and this configuration may also be applied to the circuit configuration illustrated in FIG. 2.

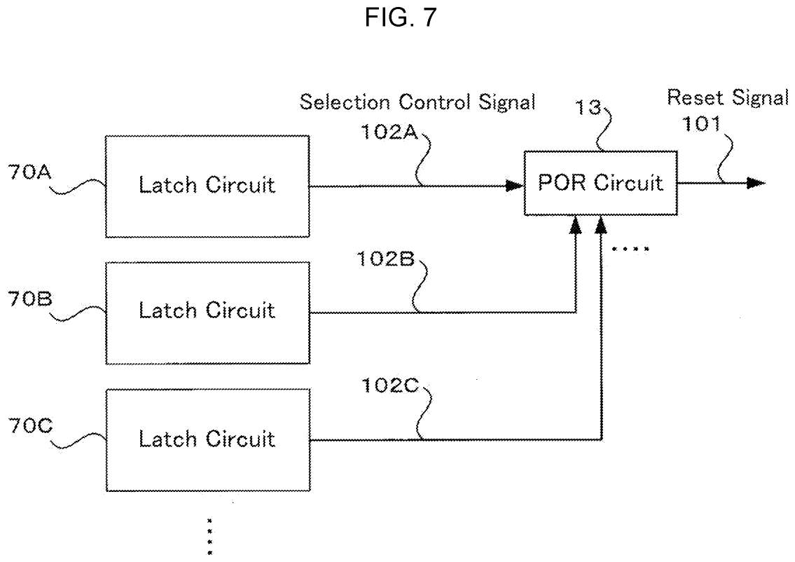

In the embodiment described above, the response characteristics to a voltage change were adjusted in the process of generating the reset signal 101 by the selection control signal 102 of one bit. Next, FIG. 7 illustrates a circuit configuration for controlling a POR circuit that can adjust the response characteristics by a plurality of bits.

The circuit configuration of FIG. 7 includes a POR circuit 13 and a plurality of latch circuits 70A, 70B, 70c and so on.

The POR circuit 13 can adjust the response characteristics to a change in power voltage in generating and outputting a reset signal after detecting a change in voltage value of the power voltage by a combination of logic values or states of a plurality of selection control signals 102A, 102B, 102C and so on, inputted from outside.

The latch circuits 70A, 70B, 70C and so on are the holding circuits for maintaining the logic values or states of the plurality of selection control signals 102A, 102B, 102C and so on, respectively. The internal configuration of the latch circuits 70A, 70B, 70C and so on and the circuit configuration of the previous stage are the same as those of the latch circuit 70 illustrated in FIG. 5.

The POR circuit 13 illustrated in FIG. 7 changes the response characteristics such as the threshold voltage for detecting a change in power voltage, the delay time, which is a period of time between when the voltage value of the power voltage reaches the threshold voltage and when the reset signal is outputted, and the like, by a combination of logic values or states of the inputted selection control signals 102A, 102B, 102C and so on.

What is claimed is:

1. A semiconductor device, comprising:
a plurality of power-on reset circuits having different response characteristics to a change in a power voltage, in generating and outputting a reset signal after detecting a change in voltage value of the power voltage; and
a selector that selects a reset signal outputted from one of the plurality of power-on reset circuits based on an inputted selection control signal.

2. A semiconductor device, comprising:
a power-on reset circuit that can switch between different response characteristics to a change in power voltage according to a predetermined setting value, in generating and outputting a reset signal by detecting a change in voltage value of the power voltage; and
a selector that selects one of a plurality of setting values for setting the response characteristics based on an inputted selection control signal, and applies the selected one of the plurality of setting values to the power-on reset circuit.

3. The semiconductor device according to claim 1, wherein the response characteristics include at least one of a threshold voltage for detecting the change in the voltage value of the power voltage or a delay time that is between a time when the voltage value of the power voltage reaches the threshold voltage and a time when the reset signal is outputted.

4. The semiconductor device according to claim 1, further comprising a holding circuit that holds a logic value of the selection signal,
wherein the semiconductor device has a circuit configuration in which an external power voltage is used for a power voltage to drive the selector and an internal power voltage generated internally in the semiconductor device is used for a power voltage to drive the holding circuit.

5. The semiconductor device according to claim 4, wherein the internal power voltage is generated by a constant voltage circuit using the external power voltage as an input.

6. The semiconductor device according to claim 1, further comprising:
a pulse signal generating circuit for generating a pulse signal having a prescribed pulse width;
a filter circuit that removes a noise component included in an output signal from the pulse signal generating circuit; and
a latch circuit that changes a logic value of the selection control signal by receiving, via the filter circuit, an input of a pulse signal generated by the pulse signal generating circuit and receiving the reset signal for reset, when the logic value of the selection control signal is to be changed.

7. The semiconductor device according to claim 6, wherein the latch circuit has a capacitor therein for holding a logical state of the selection control signal when the power voltage lowers.

8. A semiconductor device, comprising:
a power-on reset circuit that can switch between different response characteristics to a change in a power voltage by a combination of logic values of a plurality of selection control signals that are externally inputted; and
a plurality of holding circuits that hold the plurality of selection control signals, respectively.
